(19) United States
(12) Patent Application Publication
(10) Pub. No.: US 2024/0297276 A1
(43) Pub. Date: Sep. 5, 2024

(54) LIGHT-EMITTING DEVICE

(71) Applicant: TOYODA GOSEI CO., LTD., Kiyosu-shi (JP)

(72) Inventors: Yoshiki TANIYAMA, Kiyosu-shi (JP); Takeshi MATSUSHIMA, Kiyosu-shi (JP)

(21) Appl. No.: 18/421,293

(22) Filed: Jan. 24, 2024

(30) Foreign Application Priority Data
Mar. 1, 2023 (JP) 2023-031264

(51) Int. Cl. H01L 33/58; H01L 33/54

(52) U.S. Cl. CPC H01L 33/58; H01L 33/54

(57) ABSTRACT

A light-emitting device includes a substrate including a wiring on a surface thereof, a light-emitting element mounted on the substrate, a lens disposed on the substrate so as to cover the light-emitting element, an annular protrusion provided on the substrate and around the light-emitting element, and a sealing liquid disposed in a space defined under the lens to seal the light-emitting element. A shape of the sealing liquid is maintained between the substrate and a region of an inner surface of the lens above the light-emitting element by surface tension such that the sealing liquid is surrounded by an air layer in the space. A shape of a portion of the sealing liquid in contact with the substrate is maintained by the protrusion. The sealing liquid has a shape that widens laterally in a direction from the substrate to the lens.

### CROSS-REFERENCE TO RELATED APPLICATIONS

The present patent application claims the priority of Japanese patent application No. 2023/031264 filed on Mar. 1, 2023, and the entire contents of Japanese patent application No. 2023/031264 are hereby incorporated by reference.

### TECHNICAL FIELD

The present invention relates to a light-emitting device.

### BACKGROUND ART

A light-emitting module is known in which a light-emitting element is sealed in a liquid (see, e.g., Patent Literature 1). In the light-emitting module of Patent Literature 1, the inner space of a package is filled with the liquid to seal the light-emitting element.

### CITATION LIST

### Patent Literatures

Patent Literature 1: JP 2016/207754 A

### SUMMARY OF INVENTION

When a substrate of the light-emitting element is formed of a material having a large refractive index difference from air, such as sapphire, total reflection occurs at the interface between the substrate and the surrounding air. In such cases, by filling a space inside a lens with a low-refractive-index liquid such as fluorine-based oil to seal the light-emitting element, total reflection at the surface of the substrate can be reduced and light extraction efficiency can be improved.

On the other hand, however, it also causes an increase in the amount of light extracted from the side surface of the substrate of the light-emitting element, resulting in a wide light distribution.

It is an object of the invention to provide a light-emitting device in which a light-emitting element is sealed with a liquid and which can achieve narrow light distribution while increasing light extraction efficiency.

According to an aspect of the invention, provided is a light-emitting device as defined below.

(1) A light-emitting device, comprising:
a substrate comprising a wiring on a surface thereof;
a light-emitting element mounted on the substrate;
a lens disposed on the substrate so as to cover the light-emitting element;
an annular protrusion provided on the substrate and around the light-emitting element; and
a sealing liquid disposed in a space defined under the lens to seal the light-emitting element,
wherein a shape of the sealing liquid is maintained between the substrate and a region of an inner surface of the lens above the light-emitting element by surface tension such that the sealing liquid is surrounded by an air layer in the space,
wherein a shape of a portion of the sealing liquid in contact with the substrate is maintained by the protrusion, and
wherein the sealing liquid has a shape that widens laterally in a direction from the substrate to the lens.

(2) The light-emitting device defined in (1), wherein at least a portion of the region of the inner surface of the lens above the light-emitting element protrudes downward, and wherein at least a portion of a lower end of the protruding portion of the region faces an upper surface of the light-emitting element.

(3) The light-emitting device defined in (1) or (2), wherein the protrusion constitutes part of the wiring.

(4) The light-emitting device defined in (1) or (2), wherein the sealing liquid comprises a fluorine-based oil.

(5) The light-emitting device defined in (1) or (2), wherein the sealing liquid has a viscosity of not less than 0.3 Pa·s.

(6) The light-emitting device defined in (1) or (2), wherein the protrusion has a height of not less than 10 μm.

(7) A light-emitting device, comprising:
a substrate comprising a wiring on a surface thereof;
a light-emitting element mounted on the substrate;
a lens disposed on the substrate so as to cover the light-emitting element; and
a sealing liquid disposed in a space defined under the lens to seal the light-emitting element,
wherein a shape of the sealing liquid is maintained between side and upper surfaces of the light-emitting element and a region of an inner surface of the lens above the light-emitting element by surface tension such that the sealing liquid is surrounded by an air layer in the space, and
wherein the sealing liquid has a shape that widens laterally in a direction from the substrate to the lens.

### Advantageous Effects of Invention

According to an embodiment of the invention, it is possible to provide a light-emitting device in which a light-emitting element is sealed with a liquid and which can achieve narrow light distribution while increasing light extraction efficiency.

### BRIEF DESCRIPTION OF DRAWINGS

FIG. 1A is a vertical cross-sectional view showing a light-emitting device in an embodiment of the present invention.

FIG. 1B is a top view showing a substrate at around a protrusion.

FIGS. 2A and 2B are examples of cross-sectional view showing the light-emitting device taken along line A-A shown in FIG. 1A.

FIGS. 3A to 3C are vertical cross-sectional views showing modifications of the light-emitting device which are different in the shape of a region of an inner surface of a lens above a light-emitting element.

FIGS. 4A and 4B are vertical cross-sectional views showing modifications of the light-emitting device which are different in the shape of the region of the inner surface of the lens above the light-emitting element.

FIG. 5 is a vertical cross-sectional view showing a modification of the light-emitting device in the embodiment of the invention.

### DESCRIPTION OF EMBODIMENTS

### (Configuration of a Light-Emitting Device)

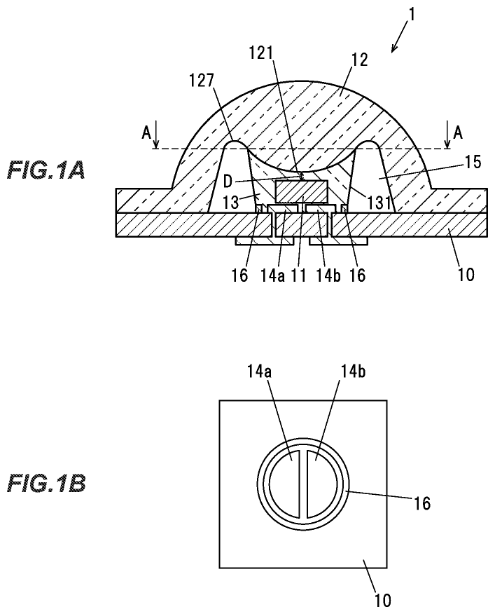

FIG. 1A is a vertical cross-sectional view showing a light-emitting device 1 in an embodiment of the invention. The light-emitting device 1 includes a substrate 10 having a wiring 14 (wirings 14a, 14b) on its surface, a light-emitting element 11 mounted on the substrate 10, a lens 12 placed on the substrate 10 so as to cover the light-emitting element 11, an annular protrusion 16 provided on the substrate 10 and located around the light-emitting element 11, and a sealing liquid 13 disposed in a space defined under the lens 12 to seal the light-emitting element 11.

In the light-emitting device 1, the shape of the sealing liquid 13 is maintained between the substrate 10 and a region 121 of an inner surface of the lens 12 above the light-emitting element 11 by surface tension such that the sealing liquid 13 is surrounded by an air layer 15 in the space inside the lens 12.

A portion of the sealing liquid 13 in contact with the substrate 10 tends to stay inside the annular protrusion 16 due to surface tension. That is, the shape of the portion of the sealing liquid 13 in contact with the substrate 10 is maintained by the protrusion 16 so that the sealing liquid 13 does not spread to the outside of the protrusion 16. A side surface 131 of the sealing liquid 13 is formed mainly between the protrusion 16 and the inner surface of the lens 12.

The light-emitting element 11 is typically an LED chip. The light emitting element 11 is also typically a flip-chip type element, but may be a face-up type element. The emission wavelength of the light-emitting element 11 is not particularly limited, and may be, e.g., a wavelength in the visible region or a wavelength in the ultraviolet region. The light-emitting element 11 may be a light-emitting element other than LED, such as a laser diode (LD).

The substrate 10 has the wiring 14 (wirings 14a, 14b) formed of Cu, etc., on its surface. An n-electrode and a p-electrode of the light-emitting element 11 are respectively connected to the wirings 14a and 14b. The light-emitting element 11, when being a flip-chip type element, is connected to the wirings 14a and 14b by a conductive bonding member formed of AuSn or solder, etc.

The sealing liquid 13 has an inverse tapered shape that broadens laterally from a lower side toward an upper side. Since this increases the angle of incidence of light emitted from the light-emitting element 11 on the side surface 131 of the sealing liquid 13, i.e., on the interface between the sealing liquid 13 and the air layer 15, the reflectance at the side surface 131 of the sealing liquid 13 increases and also total reflection is more likely to occur. Total reflection can occur because the refractive index of the sealing liquid 13 is greater than that of the air layer 15. As a result, it is possible to reduce light extracted laterally from the light-emitting element 11 and increase light extracted upward, thereby achieving a narrow light distribution.

The inverse tapered shape of the sealing liquid 13 may be a linear inverse tapered shape with straight sides when viewed in a vertical cross section as shown in FIG. 1A, or a non-linear inverse tapered shape with curved sides when viewed in a vertical cross section.

By controlling the taper angle of the side surface 131 of the sealing liquid 13, it is possible to control the direction of light reflection from the side surface 131. The taper angle of the side surface 131 can be controlled by the size of the planar pattern of the protrusion 16, the amount of the sealing liquid 13, and the shape of a portion of the inner surface of the lens 12 in contact with the sealing liquid 13, etc.

FIG. 1B is a top view showing the substrate 10 at around the protrusion 16. As described above, the protrusion 16 has an annular planar pattern. The shape of the portion of the sealing liquid 13 in contact with the substrate 10 is maintained on the inner side of the annular protrusion 16. The planar pattern here means a pattern in a direction parallel to the surface of the substrate 10.

The planar pattern of the protrusion 16 shown in FIG. 1B is a circular annular shape, but it is not limited thereto and it may be another annular shape such as polygonal annular shape. The planar pattern of the protrusion 16 may be a partially discontinued annular shape as long as it is possible to form and maintain the shape of the sealing liquid 13, but a continuous annular shape without disconnection as shown in FIG. 1B is preferable to stably form and maintain the shape of the sealing liquid 13.

To more stably maintain the shape of the portion of the sealing liquid 13 in contact with the substrate 10 by the protrusion 16, the height of the protrusion 16 is preferably not less than 10 μm. On the other hand, if the protrusion 16 is too high, absorption of light by the protrusion 16 may become so large as to affect light extraction efficiency of the light-emitting device 1. For this reason, when, e.g., the light-emitting element 11 is of a flip-chip type, the height of the protrusion 16 is preferably not more than half the height of the light-emitting element 11, e.g., not more than 200 μm.

The protrusion 16 is typically formed as a part of the wiring 14 (wirings 14a, 14b). In this case, the wirings 14a, 14b and the protrusion 16 are formed by patterning one metal film. Thus, the protrusion 16 is formed of the same material as the wirings 14a and 14b (e.g., Cu) and has the same thickness as the wirings 14a and 14b. The protrusion 16 is not connected to the wirings 14a and 14b connected to the light-emitting element 11, and is not used as a current path. The protrusion 16 does not need to be a part of the wiring 14 and may be a member that is formed of a resin material such as silicone, a ceramic material such as alumina, or a metal material such as Au or Al, and is a fixed to the upper surface of the substrate 10.

It is easier to maintain the shape of the sealing liquid 13 when a distance D between the upper surface of the light-emitting element 11 and the inner surface of the lens 12 is smaller, and it is particularly preferable that the distance D be zero, i.e., the upper surface of the light-emitting element 11 be in contact with the inner surface of the lens 12.

The distance D between the upper surface of the light-emitting element 11 and the inner surface of the lens 12 can be reduced by forming the inner surface of the lens 12 so that the region 121 above the light-emitting element is curved and protrudes downward as shown in FIG. 1A. At least a portion of a lower end of the protruding portion of the region 121 faces the upper surface of the light-emitting element 11. That is, at least the portion of the lower end of the protruding portion of the region 121 and the horizontal position of the upper surface of the light emitting element 11 overlap.

The taper angle of the side surface 131 of the sealing liquid 13 can be controlled also by the size of the protruding portion of the region 121. For example, when the size of the planar pattern of the protrusion 16 and the amount of sealing liquid 13 are held constant, the larger the protruding portion of the region 121, the larger the taper angle of the side surface 131.

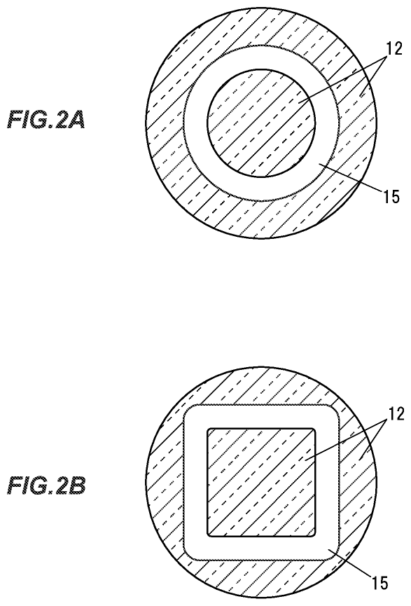

FIGS. 2A and 2B are examples of cross-sectional view showing the light-emitting device 1 taken along line A-A shown in FIG. 1A. The horizontal cross-sectional shape of the air layer 15 shown in FIGS. 2A and 2B corresponds to the planar pattern of a depression 127. In case that the region 121 of the inner surface of lens 12 protrudes downward, typically the depression 127 having an annular shape surrounds the protruding portion of the region 121, as shown in FIGS. 1A, 2A and 2B. The depression 127 is an upwardly recessed portion of the inner surface of the lens 12. In this case, the shape of the region 121 makes it easier to hold the sealing liquid 13 around the light-emitting element 11. The planar pattern of the depression 127 is, e.g., a circular annular shape as shown in FIG. 2A or a polygonal annular shape as shown in FIG. 2B.

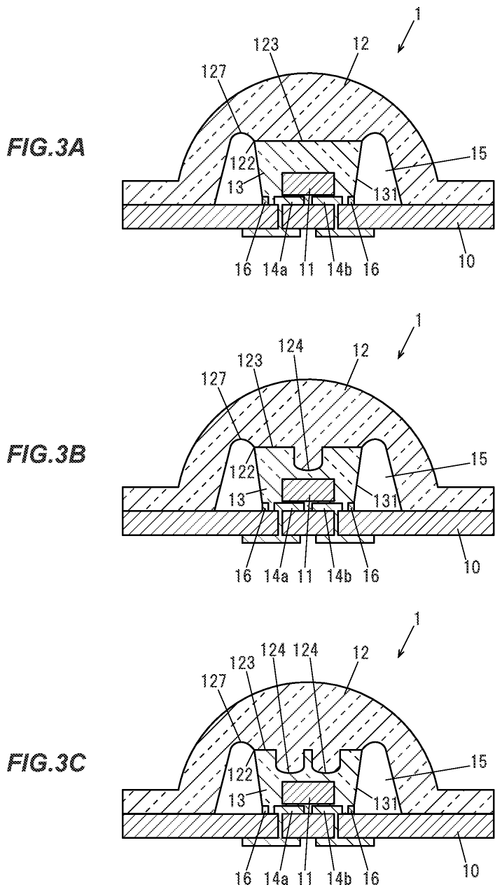

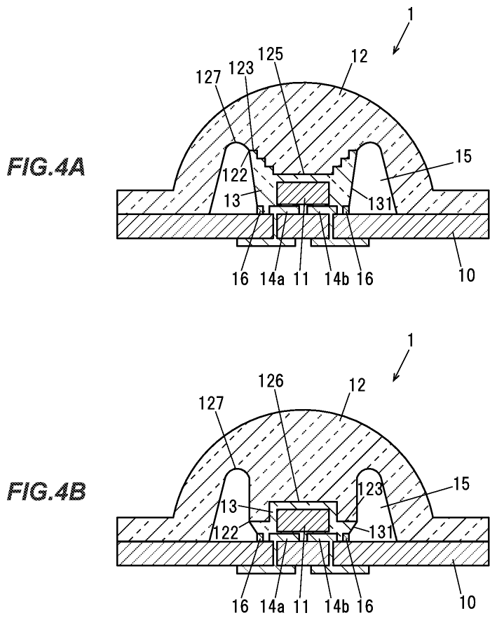

FIGS. 3A to 3C, 4A and 4B are vertical cross-sectional views showing modifications of the light-emitting device 1 which are different in the shape of the region of the inner surface of the lens 12 above the light-emitting element 11.

In the example shown in FIG. 3A, the region of the inner surface of the lens 12 above the light-emitting element 11 is provided with a flat region 123, and the depression 127 is provided therearound. A step 122 is formed between the region 123 and the depression 127, and the sealing liquid 13 tends to stay on the inner side of the step 122 due to surface tension. In other words, the shape of the portion of the sealing liquid 13 in contact with the inner surface of the lens 12 can be maintained by the step 122.

In the examples shown in FIGS. 3B and 3C, the flat region 123 is provided with one or plural protruding portions 124 that curve downward and protrude. By providing the protruding portion 124, the distance D between the upper surface of the light-emitting element 11 and the inner surface of the lens 12 can be reduced. The flat region 123 may be provided with a stepped protruding portion 125 as shown in FIG. 4A. At least a portion of the lower end of the protruding portion 124, 125 faces the upper surface of the light-emitting element 11.

In the example shown in FIG. 4B, the flat region 123 is provided with a depression 126 tailored to the shape of the light-emitting element 11, and the inner surface of the lens 12 covers the upper surface and an upper portion of the side surface of the light-emitting element 11. The position of the flat region 123 in this case is lower than the position of the upper surface of the light-emitting element 11. In this structure, the distance between the light-emitting element 11 and the inner surface of the lens 12 can be reduced over a wide range, allowing the shape of the sealing liquid 13 to be maintained more stably.

The outer shape of the lens 12 is typically a dome shape as shown in FIG. 1A, but is not limited thereto. As the material of the lens 12, e.g., quartz, alumina, fluoropolymer, etc. can be used.

The sealing liquid 13 is formed of a liquid transparent to light emitted by the light-emitting element 11, such as fluorine-based oils or water. It is preferable that the sealing liquid 13 also have heat dissipation properties, moisture barrier properties, properties to efficiently introduce light into the lens 12, and properties to hold the lens 12 by surface tension until the lens 12 is fixed to the substrate 10. For example, fluorine-based oils with moisture barrier properties are particularly preferable as the material of the sealing liquid 13.

The sealing liquid 13 having a higher viscosity maintains its shape more easily. For this reason, the viscosity of the sealing liquid 13 is preferably, e.g., not less than 0.3 Pa's, more preferably, not less than 2.5 Pa·s. The fluorine-based oils have poor wettability and can stably maintain its shape even if the viscosity is low to some extent, hence, it is preferable as the material of the sealing liquid 13. In case that the sealing liquid 13 includes a filler, the viscosity increases but light extraction efficiency decreases, hence, it is preferable that the sealing liquid 13 do not includes a filler.

A typical procedure for forming the inverse tapered sealing liquid 13 inside the lens 12 is as follows. First, the sealing liquid 13 is dropped from above the light-emitting element 11 mounted on the substrate 10. The light-emitting element 11 is thereby covered with the sealing liquid 13 having a dome shape. At this time, when dropping the sealing liquid 13 onto the light-emitting element 11, the amount of the sealing liquid 13 dropped is such that the sealing liquid 13 does not wet and spread to the outside of the protrusion 16. Next, the lens 12 is placed over the light-emitting element 11 covered with the sealing liquid 13. At this time, the dome-shaped sealing liquid 13 is squashed by the inner surface of the lens 12 and is deformed into an inverse tapered shape as shown in FIG. 1A, etc. The lens 12 and the substrate 10 are fixed by, e.g., a resin material such as silicone, or solder.

The size of the planar pattern of the protrusion 16, the amount of the sealing liquid 13, and the shape of the portion of the inner surface of the lens 12 in contact with the sealing liquid 13, etc., are adjusted so that after placing the lens 12 over the substrate 10, the sealing liquid 13 is surrounded by the air layer 15 and the shape of the sealing liquid 13 is maintained between the substrate 10 and the region 121 of the inner surface of the lens 12 above the light-emitting element 11 by surface tension.

The taper angle of the inversely tapered sealing liquid 13 can be controlled by the size of the planar pattern of the protrusion 16, the amount of the sealing liquid 13, and the shape of the portion of the inner surface of the lens 12 in contact with the sealing liquid 13, etc. For example, it is possible to increase the taper angle of the sealing liquid 13 by reducing the size of the planar pattern of the protrusion 16, by increasing the amount of sealing liquid 13, or by increasing the size of the protruding portion of the region 121 of the inner surface of the lens 12.

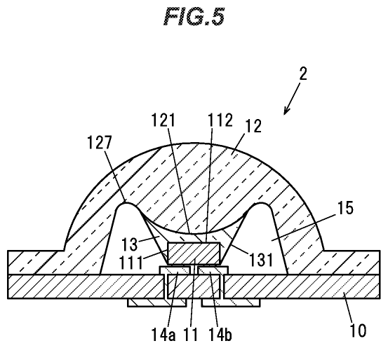

FIG. 5 is a vertical cross-sectional view showing a light-emitting device 2 which is a modification of the light-emitting device 1. The light-emitting device 2 differs from the light-emitting device 1 in that the shape of the lower side of the sealing liquid 13 is maintained by a side surface 111 of the light-emitting element 11 instead of by the protrusion 16. In this case, the side surface 131 of the sealing liquid 13 is formed mainly between the lower edge (on the substrate 10 side) of the side surface 111 of the light-emitting element 11 and the inner surface of the lens 12.

That is, in the light-emitting device 2, the shape of the sealing liquid 13 is maintained between the side surface 111 and an upper surface 112 of the light-emitting element 11 and the region 121 of the inner surface of the lens 12 above the light-emitting element 11 by surface tension such that the sealing liquid 13 is surrounded by the air layer 15 in the space inside the lens 12. The sealing liquid 13 has an inverse tapered shape that broadens laterally from the lower side toward the upper side.

### Effects of the Embodiment

In the light-emitting device 1 according to the embodiment of the invention, since the light-emitting element 11 is sealed with the sealing liquid 13 having an inverse tapered shape and the sealing liquid 13 is surrounded by the air layer 15, light extracted laterally from the light-emitting element 11 due to reflection at the side surface 131 of the sealing liquid 13 can be reduced and light extracted upward can be increased. It is thereby possible to narrow light distribution of the light-emitting device 1 and improve light collection efficiency.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention.

In addition, the embodiment described above does not limit the invention according to the claims. Further, please note that not all combinations of the features described in the embodiment are necessary to solve the problem of the invention.

### REFERENCE SIGNS LIST

1 LIGHT-EMITTING DEVICE
10 SUBSTRATE
11 LIGHT-EMITTING ELEMENT
12 LENS
121 REGION
13 SEALING LIQUID
131 SIDE SURFACE
14a, 14b WIRING
15 AIR LAYER
16 PROTRUSION

1. A light-emitting device, comprising:
a substrate comprising a wiring on a surface thereof;
a light-emitting element mounted on the substrate;
a lens disposed on the substrate so as to cover the light-emitting element;
an annular protrusion provided on the substrate and around the light-emitting element; and
a sealing liquid disposed in a space defined under the lens to seal the light-emitting element,
wherein a shape of the sealing liquid is maintained between the substrate and a region of an inner surface of the lens above the light-emitting element by surface tension such that the sealing liquid is surrounded by an air layer in the space,
wherein a shape of a portion of the sealing liquid in contact with the substrate is maintained by the protrusion, and
wherein the sealing liquid has a shape that widens laterally in a direction from the substrate to the lens.

2. The light-emitting device according to claim 1, wherein at least a portion of the region of the inner surface of the lens above the light-emitting element protrudes downward, and wherein at least a portion of a lower end of the protruding portion of the region faces an upper surface of the light-emitting element.

3. The light-emitting device according to claim 1, wherein the protrusion constitutes part of the wiring.

4. The light-emitting device according to claim 1, wherein the sealing liquid comprises a fluorine-based oil.

5. The light-emitting device according to claim 1, wherein the sealing liquid has a viscosity of not less than 0.3 Pa·s.

6. The light-emitting device according to claim 1, wherein the protrusion has a height of not less than 10 μm.

7. A light-emitting device, comprising:
a substrate comprising a wiring on a surface thereof;
a light-emitting element mounted on the substrate;
a lens disposed on the substrate so as to cover the light-emitting element; and
a sealing liquid disposed in a space defined under the lens to seal the light-emitting element,
wherein a shape of the sealing liquid is maintained between side and upper surfaces of the light-emitting element and a region of an inner surface of the lens above the light-emitting element by surface tension such that the sealing liquid is surrounded by an air layer in the space, and
wherein the sealing liquid has a shape that widens laterally in a direction from the substrate to the lens.
